(19) United States
(12) Patent Application Publication
(10) Pub. No.: US 2025/0167038 A1
(43) Pub. Date: May 22, 2025

(54) SUBSTRATE PROCESSING APPARATUS AND DETECTING METHOD OF TRAY TILTING

(71) Applicant: TES CO., LTD, Yongin-si (KR)

(72) Inventor: Jin-Hyung KIM, Yongin-si (KR)

(73) Assignee: TES CO., LTD, Yongin-si (KR)

(21) Appl. No.: 18/946,886

(22) Filed: Nov. 13, 2024

(30) Foreign Application Priority Data
Nov. 17, 2023 (KR) 10-2023-0159634

(51) Int. Cl. H01L 21/687; H01L 21/67

(52) U.S. Cl. CPC H01L 21/68764; H01L 21/67017; H01L 21/67259

(57) ABSTRACT

A substrate processing apparatus includes a chamber, a tray, and a detection sensor. The chamber provides a processing space for performing a process on a substrate on which a treatment liquid or an organic solvent is coated, using a fluid in a supercritical state. The tray is configured to allow the substrate to be seated thereon, and is configured to be loaded into an inside of the chamber and to be unloaded to an outside of the chamber, through an opening of the chamber. The detection sensor is configured to detect a tilting or a horizontal offsetting of the tray.

### CROSS-REFERENCE TO RELATED APPLICATIONS

A claim for priority under 35 U.S.C. § 119 is made to Korean Patent Application No. 10-2023-0159634 filed on Nov. 17, 2023, in the Korean Intellectual Property Office, the entire contents of which are hereby incorporated by reference.

### BACKGROUND OF THE INVENTION

### Field of the Invention

The present invention relates to an apparatus for processing a substrate and a method for detecting a tilting of a tray, and more particularly to a substrate processing apparatus and a tray tilting detection method capable of detecting the tilting or offsetting of the tray supporting the substrate when the substrate is subjected to a process, such as a drying process, using a supercritical fluid.

### Description of the Related Art

In general, when a large-scale and high-density semiconductor device such as a large scale integration (LSI) semiconductor device is fabricated on a surface of a semiconductor wafer, it is necessary to form an ultra-fine pattern on the surface of the wafer.

This ultra-fine pattern can be formed by executing various processes such as exposing, developing, and cleaning the wafer coated with a resist, patterning the resist, and then etching the wafer to transfer a resist pattern to the wafer.

After the etching, the wafer is cleaned to remove dirt or natural oxide film on the surface of the wafer. A cleaning treatment or process is performed by immersing the wafer with the patterned surface in a treatment liquid such as a chemical liquid or a rinse liquid, or by coating the treatment liquid on the surface of the wafer.

However, due to a high integration of the semiconductor device, when the treatment liquid is dried after the cleaning treatment is performed, a pattern collapse in which the pattern on the surface of the resist or wafer is destroyed, occurs.

This pattern collapse corresponds to a phenomenon that when the treatment liquid 10 remaining on the surface of the substrate S is dried after the cleaning treatment as shown in FIG. 13A, if the treatment liquid on left and right sides of the patterns 11, 12, and 13 is dried unevenly, capillary forces tensioning the patterns 11, 12, and 13 to the left and right sides are not balanced, and thus the patterns 11, 12, and 13 collapse in a direction where a relatively large amount of treatment liquid remains.

In case of FIG. 13A, a drying of the treatment liquid in left and right outer regions where no patterns are formed on a top surface of the substrate S is completed, while the treatment liquid 10 remains in gaps between the patterns 11, 12, and 13. As a result, the patterns 11 and 13 on both the left and right sides collapse inwardly due to the capillary forces from the treatment fluid 10 remaining between the patterns 11, 12, and 13.

The capillary force causing the pattern collapse discussed above is attributed to a surface tension of the treatment liquid acting at the liquid/gas interface between an atmospheric environment surrounding the substrate S after the cleaning treatment and the treatment liquid remaining between the patterns.

Therefore, recently, a processing method for drying the treatment liquid using a fluid in a supercritical state (hereinafter referred to as a “supercritical fluid”) that does not form an interface with a gas or liquid has been attracting attention recently.

In a phase diagram according to pressure and temperature of FIG. 13B, a drying method of the prior art utilizing only a temperature control indispensably passes through a gas-liquid equilibrium (or coexisting) line as shown by the dashed arrow, and thus the capillary force is generated at the gas-liquid interface.

In contrast, when the drying is performed via the supercritical state by using both temperature and pressure controls of the fluid, the gas-liquid equilibrium line is not crossed, and thus the drying of the substrate in an inherently capillary force-free state is enabled.

Referring to FIG. 13B, in the drying using the supercritical fluid, if a pressure of the liquid is increased from A to B, and then a temperature thereof is increased from B to C, the liquid switches to the supercritical state C without passing the gas-liquid equilibrium line. Further, when a drying process is over, a pressure of the supercritical fluid is lowered to D to switch to the gas without crossing the gas-liquid equilibrium line.

Meanwhile, in a conventional apparatus that performs a process such as the drying process on the substrate using the supercritical fluid as described above, a tray on which the substrate is placed is provided, and the tray is moved inside the chamber to perform the process. In this case, if the tray is vertically and horizontally aligned with and located at a predetermined correct or precise position in a center of the chamber, the process for the substrate can be performed more effectively. However, a variety of factors can cause the tray to become misaligned.

For example, one end of the tray is secured to a cover that seals an opening of the chamber, while the other end of the tray is a free end that is not secured. Therefore, as the process progresses, the unfixed or unsecured end, i.e., the free end of the tray can deflect or bend under its own weight, and thus tilting may occur. Further, when the tray is loaded into an inside or interior of the chamber, the tray can be loaded with being offset to one side in a horizontal plane.

As such, if the distances from the tray to a floor (or base), a ceiling, and an inner walls of the chamber are not kept constant and vary, the tray can be displaced out of the correct position and the treatment liquid or an organic solvent 10 on the substrate S cannot adequately protect the pattern on the surface of the substrate S, and thus this can cause damage to the pattern.

Moreover, the misalignment of the tray can cause an imbalance in the flow of the fluid supplied to the interior of the chamber, so that flow energy of the fluid is not uniformly transferred towards the substrate S. In this case, the flow energy of the fluid is not transmitted to the top surface of the substrate S, and thus the organic solvent 10, such as IPA (Isopropyl Alcohol) and the like that exists between the patterns 11, 12, and 13 of the substrate S cannot be properly substituted.

### SUMMARY OF THE INVENTION

The present invention is contemplated to solve problems in the prior art mentioned above. Thus, it is an object of the present invention to provide a substrate processing apparatus capable of detecting that a tray on which a substrate is placed in the substrate processing apparatus is not aligned with a predetermined correct position in a chamber and thus tilting or offsetting thereof occurs.

To solve the above problems, according to a first aspect of the invention, the present invention may provide a substrate processing apparatus comprising: a chamber providing a processing space for performing a process on a substrate on which a treatment liquid or an organic solvent is coated, using a fluid in a supercritical state; a tray configured to allow the substrate to be seated thereon, the tray being configured to be loaded into an inside of the chamber and to be unloaded to an outside of the chamber, through an opening of the chamber; and a detection sensor configured to detect a tilting or a horizontal offsetting of the tray.

The detection sensor may includes: an emitter provided at any one of upper and lower portions of the chamber along a moving path of the tray and configured to emit light; and a receiver provided at the other of the upper and lower portions of the chamber and configured to receive the light from the emitter. Further, the tray may be formed with a through hole through which the light from the emitter passes.

The through hole may be configured in a form of an elongated hole extending along a moving direction of the tray.

The tray may include the through holes formed at formed at a front end and a rear end of the tray along a moving direction of the tray, respectively.

A shading rib may be formed along an edge of the through hole on at least one of top and bottom surfaces of the tray in which the through hole is formed.

The tilting or the horizontal offsetting of the tray may be determined by detecting at least one of a reception of the light at the receiver, a reception duration of the light, and a reception sensitivity of the light.

Meanwhile, according to a second aspect of the invention, the present invention may provide a tray tilting detection method for a substrate processing apparatus, which includes a chamber providing a processing space for performing a process on a substrate, using a fluid in a supercritical state, and a tray configured to allow the substrate to be seated thereon, the tray being configured to be loaded into an inside of the chamber and to be unloaded to an outside of the chamber, through an opening of the chamber, the method comprising: receiving, by a receiver, light which is emitted by an emitter and passes through a through hole of the tray, while the tray is moving; and determining a tilting or a offsetting of the tray by detecting at least one of a reception of the light at the receiver, a reception duration of the light, and a reception sensitivity of the light.

The through hole may include a first hole formed at a front end of the tray, and a second hole formed at a rear end of the tray.

When, upon movement of the tray, the reception durations measured at the first hole and the second hole are shorter than a pre-stored reference reception duration, it may be determined that the tray is tilted about a first axis perpendicular to a direction of the movement of the tray.

Further, when, upon movement of the tray, the reception sensitivities measured at the first hole and the second hole are smaller than a pre-stored reference reception sensitivity, it may be determined that the tray is tilted about a second axis parallel to a direction of the movement of the tray.

Further, when the light is not received by the receiver at both the first hole and the second hole, it may be determined that the tray is offset by being moved horizontally along a first axis perpendicular to a direction of the movement of the tray.

Further, during movement of the tray, when no light is detected at any one of the first and second holes, or the reception sensitivity and the reception duration detected at any one of the first and second holes are less than a reference reception sensitivity and a reference reception duration, and when the reception sensitivity and the reception duration detected at the other of the first and second holes are similar to the reference reception sensitivity and the reference reception duration, it may be determined that the tray is turned on a horizontal plane.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a block diagram illustrating a configuration of a substrate processing apparatus using a supercritical fluid according to the present invention;

FIG. 2 is a side sectional view illustrating a configuration of a chamber;

FIG. 3 is a side view illustrating a tray tilted with respect to a first axis (X-axis) parallel to a horizontal plane;

FIGS. 4A and 4B are front views illustrating a state in which the tray is tilted with respect to a second axis (Y-axis) parallel to the horizontal plane, and a state in which the tray is offset to one side in an inside of the chamber along the first axis (X-axis) parallel to the horizontal plane, respectively;

FIGS. 5 and 6 are side views each illustrating a detection sensor for detecting a tilting or horizontal offsetting of the tray when the tray is moved away from the chamber;

FIG. 7 is a plan view illustrating the tray having a through hole through which light from the detection sensor passes;

FIGS. 8A and 8B are a side view illustrating a length of the through hole detected by the detection sensor when the tray is normally positioned and moving, and a side view illustrating a length of the through hole detected by the detection sensor when the tray is tilted about the first axis (X-axis) parallel to the horizontal plane, respectively;

FIGS. 9A and 9B are side views of the tray viewed from the front, illustrating a width of the through hole detected by the detection sensor when the tray is normally positioned and a width of the through hole detected by the detection sensor when the tray is tilted about the second axis (Y-axis), respectively;

FIGS. 10A and 10B are side views each illustrating a through hole of a tray according to another embodiment;

FIG. 11 is a plan view illustrating the tray moving entirely along the first axis (X-axis);

FIGS. 12A and 12B are plan views each illustrating a state in which the tray is turned along a horizontal plane with respect to the second axis (Y-axis); and

FIGS. 13A and 13B are a schematic diagram illustrating a collapse of a pattern when the pattern of a top surface of the substrate is dried according to the prior art, and a phase diagram illustrating pressure and temperature changes of a fluid in a process using the supercritical fluid, respectively.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a structure of a substrate treatment apparatus according to an embodiment of the present invention will be described in detail with reference to the accompanying drawings.

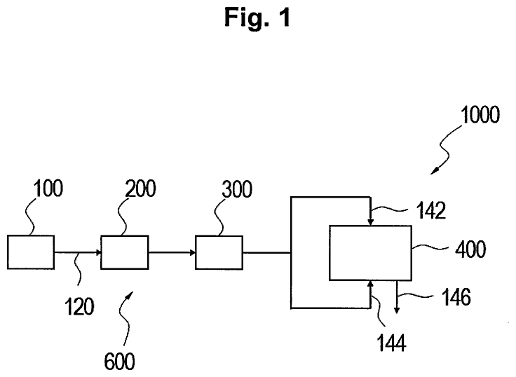

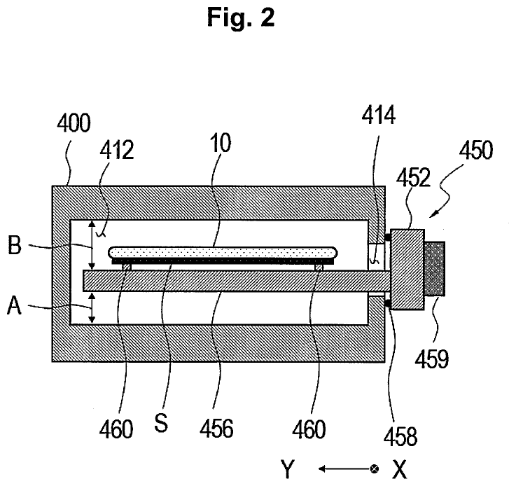

FIG. 1 is a block diagram illustrating a configuration of a substrate processing apparatus 1000 using a supercritical fluid of the present invention, and FIG. 2 is a side sectional view illustrating a configuration of a chamber 400.

The substrate processing apparatus 1000 according to the present invention performs a process on a substrate S by utilizing a fluid in a supercritical state, i.e., a supercritical fluid. Here, a supercritical fluid corresponds to a fluid having a phase that is formed when a substance reaches a critical state, that is, a state in which a critical temperature and a critical pressure are exceeded. Such supercritical fluid has a molecular density close to that of a liquid, but a viscosity close to that of a gas. Therefore, the supercritical fluid has excellent diffusion, penetration, and solubility, which are favorable for chemical reactions. Further, since the supercritical fluid has almost no surface tension and thus does not apply surface tension to any microstructure, the supercritical fluid is very useful in a drying process of semiconductor devices, not only because a drying efficiency is excellent, but also because a pattern collapse phenomenon can be avoided.

In the present invention, Carbon Dioxide (CO₂) may be used as the supercritical fluid. Carbon Dioxide has a critical temperature of approximately 31.1° C. and a relatively low critical pressure of 7.38 Mpa, and thus there are advantages that Carbon Dioxide is easily converted to the supercritical state, the state thereof is easily controlled by adjusting the temperature and pressure, and the cost is low.

In addition, Carbon Dioxide is non-toxic and harmless for human body, and has characteristics of being non-combustible and inert. Further, Carbon Dioxide in the supercritical state has a diffusion coefficient that is approximately 10 times to 100 times higher than that of water or other organic solvents. Thus, supercritical Carbon Dioxide has very good permeability, so that the substitution of organic solvents is rapidly achieved, and has almost no surface tension, which is advantageous for use in the drying process. Furthermore, it is possible to separate and reuse the organic solvent by converting Carbon Dioxide used in the drying process into a gas state, so that it is less burdensome in terms of environmental contamination.

Referring to FIG. 1 and FIG. 2, the substrate processing apparatus 1000 may include a chamber 400 providing a processing space 412 for performing using the fluid in the supercritical state, the process for the substrate S on which a treatment liquid or an organic solvent 10 (hereinafter referred to as an “organic solvent”) is coated, and a fluid supply unit 600 for supplying fluid to an inside or interior of the chamber 400.

The fluid supply unit 600 may supply fluid into the chamber 400 by regulating at least one of a temperature and a pressure of the fluid.

For example, the fluid supply unit 600 may include a fluid container 100 storing the fluid, and a main supply line 120 connecting the fluid container 100 and the chamber 400.

In this case, a pressure regulator 200 and a temperature regulator 300 may be arranged along the main supply line 120. The order of the pressure regulator 200 and the temperature regulator 300 in the main supply line 120 is exemplary, and a configuration in which the temperature regulator 300 is disposed first and the pressure regulator 200 is disposed at an end of the main supply line 120 is likewise available.

In this case, the pressure regulator 200 may be configured, for example, as a pressure pump and the like, and the temperature regulator 300 may be configured as a heater or a heat exchanger or the like for heating the fluid.

Moreover, a sensing unit or a sensor (not shown) for sensing or detecting at least one of the pressure and the temperature of the fluid may be further provided to the main supply line 120. According to the pressure and temperature detected by the sensing unit, the pressure and temperature of the fluid flowing in the main supply line 120 may be regulated. For this purpose, the substrate processing apparatus 1000 according to one embodiment of the present invention may include a control unit or a controller (not shown) for controlling the pressure regulator 200 and temperature regulator 300. The control unit may control the pressure regulator 200 and temperature regulator 300 based on the pressure and temperature detected by the sensing unit.

Meanwhile, when the process is performed on the substrate S, a temperature and a pressure of the processing space 412 of the chamber 400 should be maintained at critical temperature and pressure or above the critical temperature and pressure so that the fluid supplied inside the chamber 400 can be converted to the supercritical state.

To this end, during movement of the fluid along the main supply line 120, the fluid may be pressurized to the critical pressure or above by the pressure regulator 200, and the fluid may also be heated to the critical temperature or above by the temperature regulator 300.

Meanwhile, the main supply line 120 may be divided into a first supply line 142, which is connected to an upper part of the chamber 400, and a second supply line 144, which is connected to a lower part of the chamber 400. In this case, although not shown in accompanying drawings, the first supply line 142 and the second supply line 144 may each be provided with a valve to regulate the supply of fluid.

If the fluid is supplied through the upper part of the chamber 400 from an initial stage of the process, a fluid of high pressure may be supplied from the upper part of the chamber 400 towards the substrate S. In this case, the pattern (not shown) formed on a top portion of the substrate S may be damaged by the suppled fluid of high pressure. Therefore, at the initial stage of the process, the fluid is supplied from the lower part of the chamber 400 via the second supply line 144 to prevent damage to the pattern on the substrate S. After the pressure inside the chamber 400 reaches the process pressure, the fluid may be supplied from the upper part of the chamber 400 via the first supply line 142.

Further, the chamber 400 may be further provided with a discharge line 146 for discharging fluid from the processing space 412 to an outside thereof. During the process for the substrate S, or at the completion of the process, fluid may be discharged from the inside of the chamber 400 to the outside via the discharge line 146.

Meanwhile, the chamber 400 may provide the processing space 412 for performing the process, such as a drying process, on the substrate S using the fluid in the supercritical state.

The chamber 400 may be formed with an opening 414 at one side thereof, and may be fabricated from a material suitable for handling high pressure processes on the substrate S at the inside thereof.

The processing space 412 of the chamber 400 may be hermetically sealed, so that the pressure of the fluid supplied to the processing space 412 may be maintained above the critical pressure.

Further, the chamber 400 may be further provided with a heating unit or a heater (not shown) to maintain the temperature of the processing space 412 at or above a predetermined temperature. With the heating unit, the temperature of the processing space 412, or the temperature of the fluid received in the processing space 412, may be maintained above the critical temperature during the process on the substrate S.

Meanwhile, the chamber 400 may be provided with a substrate support unit for supporting the substrate S. In the present embodiment, the substrate support unit may be configured as a tray unit 450.

The tray unit 450 may be loaded into the processing space 412 of the chamber 400 through the opening 414 or may be unloaded from the processing space 412 to an outside of the chamber 400, through the opening 414.

For example, the tray unit 450 may include a tray 456 having a supporter 460 protruding therefrom for supporting the substrate S and configured to be loaded into the interior or the inside of the chamber 400 through the opening 414 of the chamber 400 and to be unloaded from the exterior or the outside of the chamber 400 through the opening 414, and a cover 452 provided at one end of the tray 456 to seal the opening 414.

The tray 456 may allow the substrate S to be seated and supported on a top surface thereof. A plurality of supporters 460 may be formed on the top surface of the tray 456 to support the substrate S. The substrate S may be rested on and supported by a top end of the supporter 460.

Meanwhile, the cover 452 may be connected to one end of the tray 456.

When the tray 456 is inserted into the processing space 412 through the opening 414, the cover 452 seals the opening 414. In this case, a sealing member 458 may be provided for sealing between the cover 452 and the chamber 400.

Meanwhile, when the opening 414 is sealed by the cover 452, since a high pressure process is conducted in the inside of the chamber 400 using the supercritical fluid, a configuration that prevents the cover 452 from being pushed by the pressure of the inside of the chamber 400 is required.

For example, the tray unit 450 may include a shutter 459 that pressurizes the cover 452 against being pushed by the pressure from the interior of the chamber 400. The shutter 459 pressurizes the cover 452 when the tray 456 is inserted into the processing space 412 and the cover 452 blocks the opening 414, so that the cover 452 is not pushed out during the process. The shutter 459 may press the cover 452 from an outer surface of the cover 452 toward the chamber 400. Such a configuration for pressing the cover 452 is described as an example and may be applied in a number of variations.

In the foregoing configuration, it is important that when the tray 456 is coupled to the chamber 400, the tray 456 is aligned with and located at a predetermined correct or precise position of a center in vertical and horizontal directions, within the chamber 400.

For example, it is important to maintain a first distance A between a bottom surface of the tray 456 and a base or floor of the processing space 412, and a second distance B between a top surface of the tray 456 and a ceiling of the processing space 412 to be constant, as shown in the drawings. If the first distance A and the second distance B are changed, the organic solvent 10 on a top surface of the substrate S may be gathered or cluster to one side and may not protect the pattern. Hereinafter, such tilting and offsetting of the tray 456 will be described in detail with reference to the drawings.

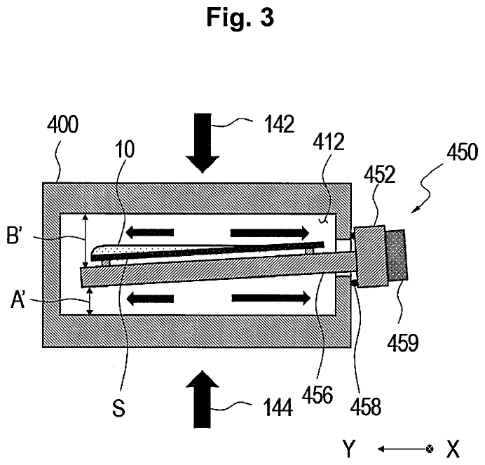

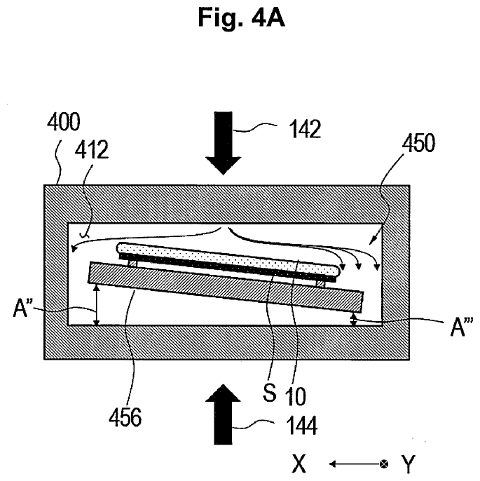

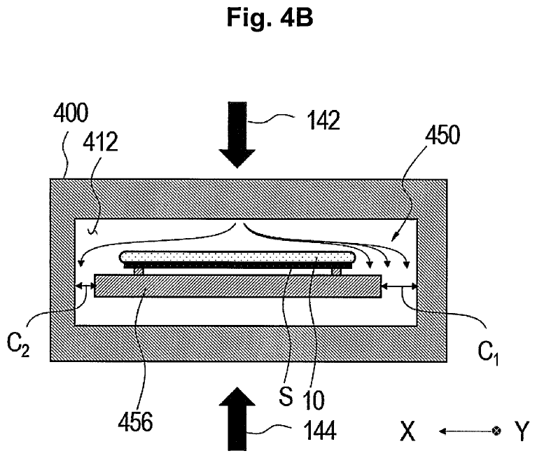

FIGS. 3, 4A, and 4B are drawings illustrating cases in which the tray 456 is tilted within the chamber 400 and offset or off-centered to one side within the chamber 400.

First, FIG. 3 is a side view illustrating the case in which the tray 456 is tilted about or with respect to a first axis (X-axis) parallel to a horizontal plane.

Referring to FIG. 3, one end of the tray 456 corresponds to a fixed end which is connected and secured to the cover 452 as described above, and the other end of the tray 456 corresponds to a free end which is not fixed. Therefore, as the process for the substrate S is repeated, the other end corresponding to the free end of the tray 456 may be tilted by deflection or bending under its own weight. In addition, the tilting may also occur in the tray 456 by the fluid of high pressure supplied to the interior of the chamber 400.

When the tilting occurs to the tray 456 as such, the first distance A′ and the second distance B′ described above are not kept constant, but are changed by the tilting of the tray 456.

As a result, the tilting of tray 456 may cause loss of the organic solvent 10 on top of the substrate S, which may result in inadequate protection of the pattern on the top surface of the substrate S, and thus cause damage to the pattern. Further, such a tilting may cause an imbalance in the flow of the fluid supplied to the interior of the chamber 400, so that flow energy of the fluid is not uniformly transferred or transmitted toward the substrate S. In this case, when the flow energy of the fluid is not transferred to the top surface of the substrate S, or is not transferred uniformly to the top surface, the organic solvent 10, such as IPA (Isopropyl Alcohol) and the like, existing between the patterns (not shown) of the substrate S may not be properly substituted.

Alternatively, FIG. 4A is a front view illustrating a case in which the tray 456 is tilted about or with respect to a second axis (Y-axis) parallel to the horizontal plane.

Referring to FIG. 4A, the tray 456 may be tilted with respect to the second axis and coupled when the tray 456 is loaded into the interior of the chamber 400.

In this case, as shown in FIG. 4A, the tray 456 may be tilted with respect to the second axis (Y-axis) so that the first distances A″ and A′″ on right and left sides of the tray 456 may be different from each other. Further, although not shown in FIG. 4A, the second distances B as described above on the right and left sides of the tray 456 may of course be changed.

As a result, even in this case, the pattern of the substrate S may be damaged by the loss of the organic solvent 10, or the organic solvent 10 may not be properly substituted, as discussed with reference to FIG. 3.

Meanwhile, FIG. 4B is a front view illustrating the case in which the tray 456 is moved horizontally along the first axis (X-axis) direction and is offset or off-centered to one side within the processing space 412.

Referring now to FIG. 4B, when the tray 456 is coupled to the chamber 400, the tray 456 may be positioned with being offset or off-centered to one side due to various factors. In FIG. 4B, a case in which the tray 456 is offset (or off-centered) and coupled to the chamber 400 by moving parallel to the first axis (X-axis), is illustrated. Further, the tray 456 in FIG. 4B may be described as being skewed to one side within the processing space 412.

Thus, considering a third distance between the tray 456 and an inner side wall of the processing space 412 or the chamber 400, it can be seen that a third distance C1 between the tray 456 and one inner side wall is relatively larger than a third distance C2 between the tray 456 and the other inner side wall.

In this case, as shown in the FIG. 4B, such a offsetting or off-centering may cause an imbalance in the flow of the fluid supplied to the interior of the chamber 400, so that the flow energy of the fluid may not be uniformly transferred toward the substrate S. Thus, the flow energy of the fluid may not be transferred to the top surface of the substrate S, or the organic solvent 10, such as IPA (Isopropyl Alcohol) and the like, present between the patterns (not shown) of the substrate S may not be properly substituted.

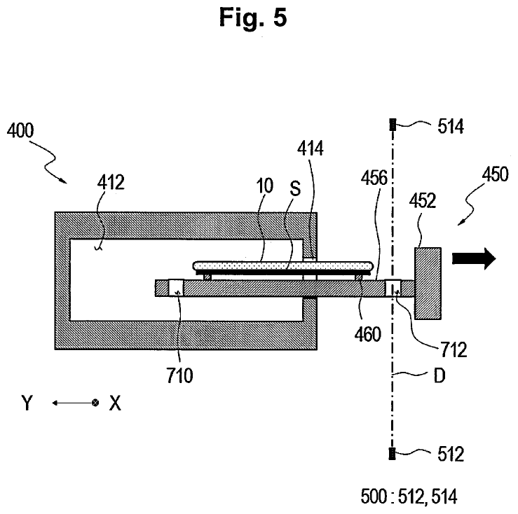

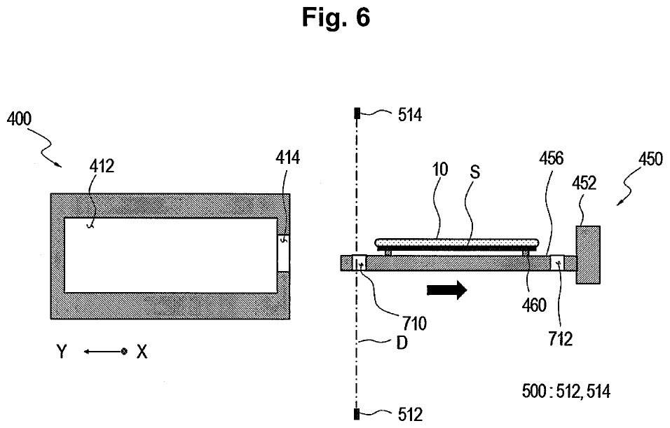

FIGS. 5 and 6 are side views each illustrating a detection sensor 500 for detecting tilting or horizontal offsetting of the tray 456 when the tray 456 is moved in a direction spaced apart from the chamber 400.

Referring to FIGS. 5 and 6, the detection sensor 500 may include an emitter 512 provided at or near one of upper and lower portions (or regions) of the chamber 400 along or with respect to a travelling or moving path of the tray 456 to emit light, and a receiver 514 provided at or near the other of the upper and lower portions (or regions) of the chamber 400 to receive the light from the emitter 512.

For example, the emitter 512 may be provided at or near the lower portion (or the lower region) of the chamber 400 along or with respect to the travelling or moving path of the tray 456, and the receiver 514 may be provided at or near the upper portion (or the upper region) of the chamber 400 along or with respect to the travelling or moving path of the tray 456.

The emitter 512 may be configured to irradiate or emit, for example, a laser or the like, and the receiver 514 may be configured to receive the laser and the like.

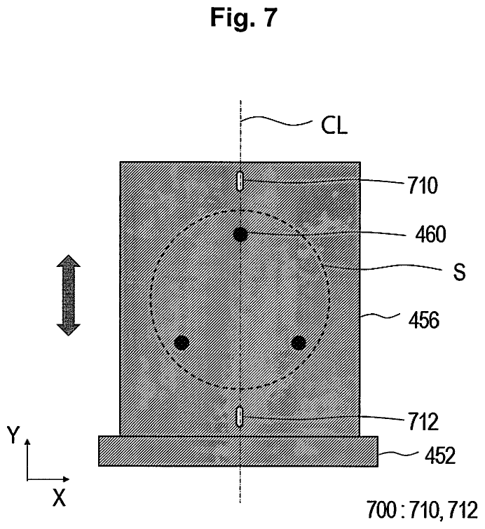

In this case, the tray 456 may be formed with at least one through hole 700 (see FIG. 7) through which the light from the emitter 512 passes.

FIG. 7 is a plan view of the tray 456, showing the through hole 700 formed at the tray 456.

Referring to FIG. 7, the through hole 700 may be formed at the tray 456 along a direction of travel or movement of the tray 456, or along a direction parallel to the direction of travel or movement of the tray 456.

Additionally, the through hole 700 may comprise a single through hole, but may comprise a plurality of through holes to more accurately detect tilting or offsetting of the tray 456.

For example, as shown in FIG. 7, the through hole 700 may comprise two through holes, which are a first hole 710 formed at a front end of the tray 456 and a second hole 712 formed at a rear end of the tray 456.

In this case, the first hole 710 and the second hole 712 may be disposed at the tray 456 along a center line CL of the tray 456. Obviously, the first hole 710 and the second hole 712 may be spaced apart from the center line CL of the tray 456. However, in order to accurately measure the tilting or offsetting of the tray 456, it is preferred that the first hole 710 and the second hole 712 are disposed along the center line CL.

Meanwhile, the first hole 710 and the second hole 712 may be disposed spaced apart by a predetermined distance in the tray 456 along the second axis (Y-axis) or along the direction of movement of the tray 456. The distance by which the first hole 710 and the second hole 712 are spaced apart from each other is not limited to a specific numerical value. However, the further the first hole 710 and second hole 712 are spaced apart from each other, the more accurately the tilting or offsetting of the tray 456 may be detected. Accordingly, as described above, the first hole 710 may be provided at the front end of the tray 456, and the second hole 712 may be provided at the rear end of the tray 456.

In addition, when the tray 456 is loaded or seated on the substrate S, the first hole 710 and the second hole 712 may be formed in an area of the tray 456 that is not covered by the substrate S so that the light passing through the through hole 700 is not interfered with the substrate S.

Meanwhile, the through hole 700 may be configured in the form of an elongated hole extending along the direction of movement of the tray 456. For example, if the through hole 700 simply has a circular shape, the time period for the light emitted by the emitter 512 to pass through the through hole 700 may be relatively too short to enable accurate detection.

Thus, in order to more accurately detect the light from the emitter 512 and furthermore to more accurately detect the tilting or offsetting of the tray 456 as will be described later, the through hole 700 may be formed in the form of the elongated hole.

In the present embodiment, both the first hole 710 and the second hole 712 are shown as having the same shape, but this is only an example, and it is possible for the holes 710 and 712 to have different shapes.

Referring back to FIGS. 5 and 6, the tilting or offsetting of the tray 456 may be detected by the detection sensor 500 when the tray 456 is moved to be inserted into the interior of the chamber 400, or when the tray 456 is separated from the chamber 400 and moved away from the chamber 400.

Hereinafter, a situation will be assumed and discussed in which the tray 456 is detected by the detection sensor 500 when the tray 456 is separated from the chamber 400 and is moved in a direction to be spaced apart therefrom. In this case, when the process for the substrate S is ended and the tray 456 is separated from the chamber 400, a degree or an amount of tilting or offsetting of the tray 456 is detected, and the tray 456 may be aligned in the predetermined correct or precise position, such that the subsequent process can be performed more accurately.

A method of detecting the tilting or offsetting of the tray 456 by the detection sensor 500 may include a step of receiving light emitted by the emitter 512 at the receiver 514 while the tray 456 is moving, and then a step of determining the tilting or offsetting of the tray 456 by detecting at least one of the followings: a reception of the light at the receiver 514 (i.e., whether the light is received at the receiver 514); a duration of the reception of the light (i.e., a period of time for which the light is received at the receiver 514); and a sensitivity or an intensity of the reception of the light (i.e., a degree or an amount of the light which is received at the receiver 514). Such a detecting method will be discussed in more detail below.

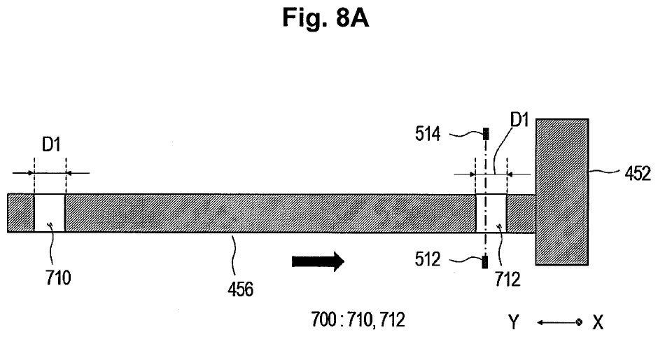

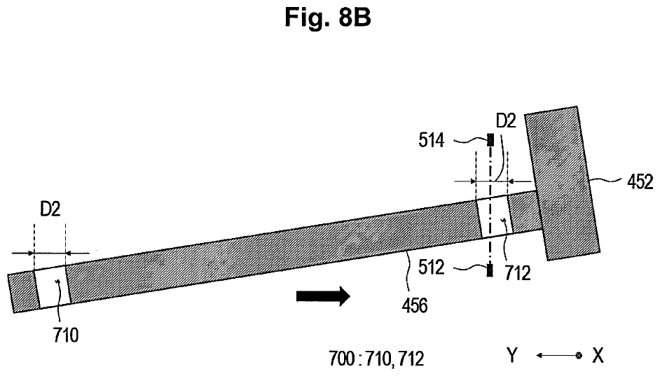

FIG. 8A is a side view illustrating a length of the through hole 700 as detected by the detection sensor 500 when the tray 456 is normally disposed and moving, and FIG. 8B is a side view illustrating a length of the through hole 700 as detected by the detection sensor 500 when the tray 456 is tilted about or with respect to the first axis (X-axis) parallel to the horizontal plane.

Referring to FIGS. 8A and 8B, it is seen that when the tray 456 is normally positioned and moved as shown in FIG. 8A, a length over which the light emitted by the emitter 512 of the detection sensor 500 is received by the receiver 514, corresponds to a first length D1 of the second hole 712. That is, the light may be received by the receiver 514 for a first reception duration (or period) of light corresponding to the first length D1. The same is applicable even when the tray 456 continues to move such that the light is received by the receiver 514 at the first hole 710. The first reception duration described above may be measured in advance according to the length of the through hole 700 and the like, and may be stored in advance as a reference reception duration in the control unit or the controller (not shown) or the memory unit (not shown) of the substrate processing apparatus 1000.

Alternatively, when the tray 456 is tilted about the first axis (X-axis) as shown in FIG. 8B, the length of the first hole 710 or the second hole 712 taken along or with respect to the horizontal plane changes to a second length D2. That is, the second length D2 becomes shorter than the first length D1 according to the extent or degree to which the tray 456 is tilted.

When the tray 456 is tilted and moved as shown in FIG. 8B, the reception duration of light detected by the receiver 514 at the first hole 710 or the second hole 712 may correspond to a second reception duration that is shorter than the first reception duration (i.e., the reference reception duration) as described above.

Thus, if, upon movement or travelling of the tray 456, the reception durations measured at the first hole 710 and the second hole 712 are all shorter than a pre-stored first reception duration (the reference reception duration), the control unit may determine that the tray 456 is tilted about the first axis (X-axis) perpendicular to the direction of movement of the tray 456.

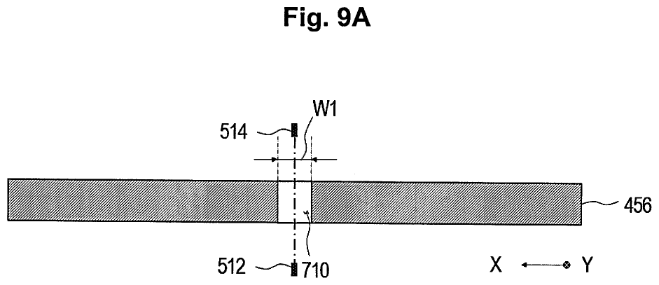

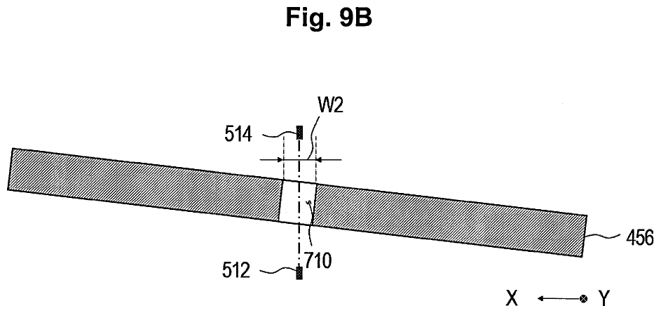

FIGS. 9A and 9B are side views of a tray viewed from the front. Particularly, FIG. 9A is the side view illustrating a width of the through hole 700 detected by the detection sensor 500 when the tray 456 is normally positioned, and FIG. 9B is the side view illustrating a width of the through hole 700 detected by the detection sensor 500 when the tray 456 is tilted about or with respect to the second axis (Y-axis).

Referring to FIGS. 9A and 9B, it is seen that when the tray 456 is normally disposed and moved as shown FIG. 9A, a width over which the light emitted by the emitter 512 of the detection sensor 500 is received by the receiver 514 corresponds to a first width W1 of the first hole 710. That is, the light may be received by the receiver 514 with a first reception sensitivity (or intensity) of light corresponding to the first width W1. The same is also applicable even when the tray 456 continues to move so that the light is received by the receiver 514 at the second hole 712. The first reception sensitivity (or intensity) described above may be measured in advance according to the width of the through hole 700 and the like, and may be stored in advance as a reference reception sensitivity (or intensity) in the control unit or the controller (not shown) or the memory unit (not shown) of the substrate processing apparatus 1000.

Alternatively, when the tray 456 is tilted about the second axis (Y-axis) as shown in FIG. 9B, the width of the first hole 710 or the second hole 712 taken along or with respect to the horizontal plane changes to a second width W2. That is, the second width D2 becomes shorter than the first width D1 according to the extent or degree to which the tray 456 is tilted.

When the tray 456 is tilted and moved as shown in FIG. 9B, the reception sensitivity or intensity of light detected by the receiver 514 through the first hole 710 or the second hole 712 may correspond to a second reception sensitivity or intensity that is smaller or less than the first reception sensitivity of intensity (i.e., the reference reception sensitivity or intensity) as described above.

Accordingly, if, upon movement or travelling of the tray 456, the reception sensitivities or intensities measured at the first hole 710 and the second hole 712 are all smaller or less than a pre-stored first reception sensitivity or intensity (the reference reception sensitivity or intensity), the control unit may determine that the tray 456 is tilted about the second axis (Y-axis) parallel to the direction of movement of the tray 456.

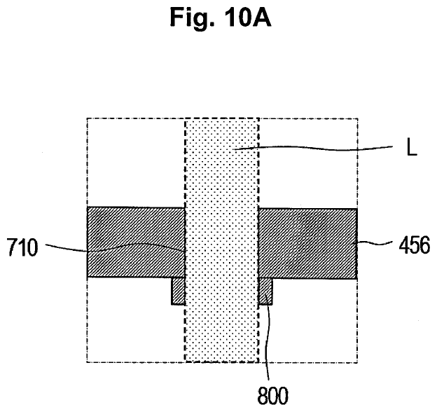

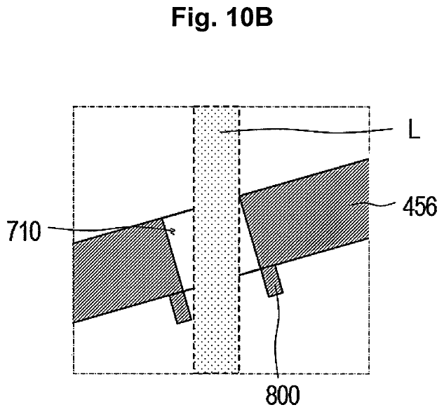

Meanwhile, FIGS. 10A and 10B are sectional views each illustrating a through hole 700 according to another embodiment of the present invention. FIG. 10A illustrates a case in which the tray 456 is parallel to the horizontal plane, and FIG. 10B illustrates a case in which the tray 456 is tilted with respect to the horizontal plane.

Referring to FIG. 10A, a shading rib 800 may be formed along an edge of the through hole 700 on at least one of the top or bottom surface of the tray 456 at which the through hole 700 is formed.

For example, as shown in FIG. 10A, the shading rib 800 may be formed along the edge of the first hole 710 on the bottom surface of the tray 456, with protruding by a predetermined height.

Such a shading rib 800 is used to more clearly distinguish the tray 456 normally aligned from the tray 456 abnormally aligned (i.e., tilted or offset), when the light is received by the receiver 514.

That is, as shown in FIG. 10B, when the tray 456 is tilted with respect to the horizontal plane, a width of the light L passing through the first hole 710 (or the second hole 712) becomes significantly smaller than the width in FIG. 10A, due to the height of the shading rib 800. In this case, the sensitivity or intensity of the light received by the receiver 514 becomes significantly smaller or less than the normal first reception sensitivity or intensity (i.e., the reference reception sensitivity or intensity), and can be distinguished more clearly.

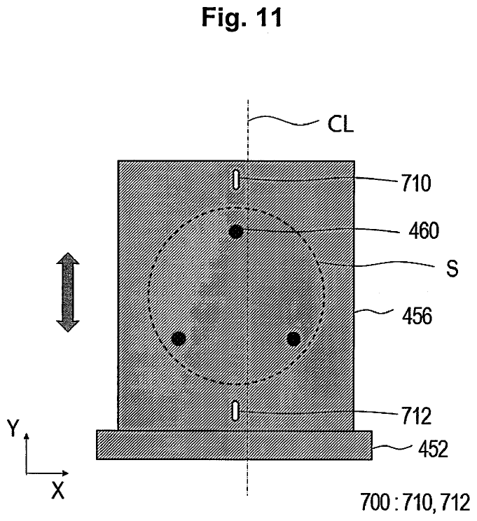

Meanwhile, FIG. 11 is a plan view illustrating a case in which the tray 456 is moved overall along the first axis (X-axis) perpendicular to the direction of movement thereof.

Referring to FIG. 11, when the tray 456 is entirely moved along the first axis (X-axis), the tray 456 is moved while the through hole 700 is spaced apart from the center line CL when compared to FIG. 7 as discussed above.

Accordingly, when the tray 456 is moved in the state as shown in FIG. 11, the light is not received by the receiver 514 of the detection sensor 500 at both the first hole 710 and the second hole 712. As such, when the light is not received at both the first hole 710 and the second hole 712, the control unit may determine that the tray 456 is offset or off-centered by being moved horizontally along the first axis (X-axis) perpendicular to the direction of movement of the tray 456.

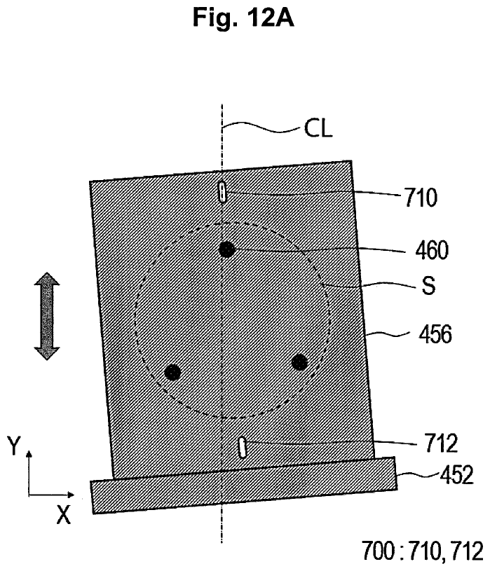

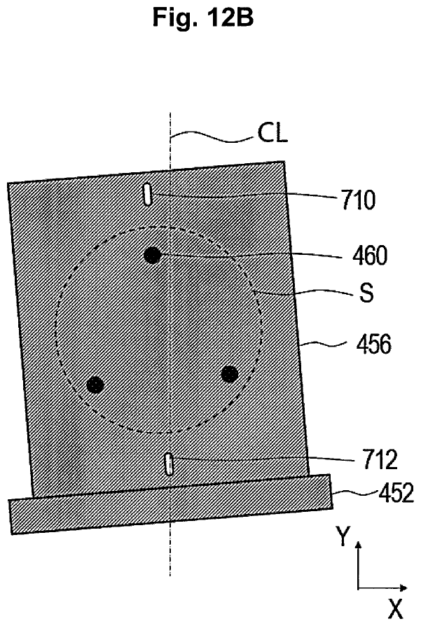

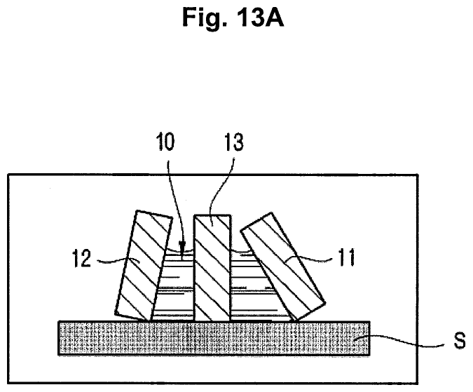

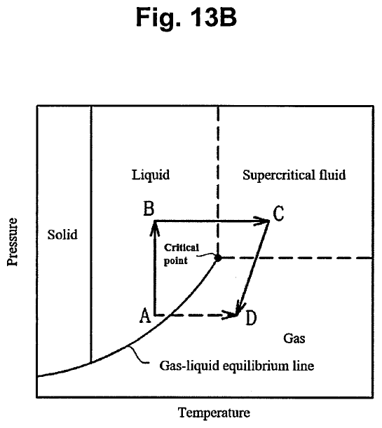

Meanwhile, FIGS. 12A and 12B are plan views each illustrating a case in which the tray 456 is turned from or with respect to the second axis (Y-axis) along the horizontal plane.

As shown in FIG. 12, the misalignment of the tray 456 also includes the tray 456 turned in or on the horizontal plane.

In this case, the first hole 710 may be located on the center line CL and the second hole 712 may be spaced apart from the center line CL, as shown in FIG. 12A, or the first hole 710 may be spaced apart from the center line CL and the second hole 712 may be located on the center line CL, as shown in FIG. 12B.

In case of FIG. 12A, the reception sensitivity and the reception duration of light received by the receiver 514 at the first hole 710 may be similar to the first reception sensitivity (the reference reception sensitivity) and the first reception duration (the reference reception duration) described above. However, at the second hole 712, the light may not be received by the receiver 514, or the reception sensitivity and reception duration may be significantly smaller and shorter than the first reception sensitivity (the reference reception sensitivity) and first reception duration (the reference reception duration) described above.

Further, in case FIG. 12B, the reception sensitivity and the reception duration of light received by the receiver 514 at the second hole 712 may be similar to the first reception sensitivity (the reference reception sensitivity) and the first reception duration (the reference reception duration) described above. However, at the first hole 710, the light may not be received by the receiver 514, or the reception sensitivity and reception duration may be significantly smaller and shorter than the first reception sensitivity (the reference reception sensitivity) and first reception duration (the reference reception duration) described above.

Therefore, during movement or travelling of the tray 456, if no light is detected at any one of the first and second holes 710 and 712 or the reception sensitivity and reception duration of the light that is detected at any one of the first and second holes 710 and 712 are significantly less (i.e., approximately 50% or less) than the first reception sensitivity (the reference reception sensitivity) and the first reception duration (the reference reception duration), and if the reception sensitivity and reception duration of the light detected at the other of the first and second holes 710 and 712 are similar to (i.e., are the same as or included within a certain margin of) the first reception sensitivity (the reference reception sensitivity) and the first reception duration (the reference reception duration), it can be determined that the tray 456 is turned in the horizontal plane.

The substrate processing apparatus and the tray tilting detection method according to the present invention have the technical advantages as follows.

According to the present invention having the configuration as discussed above, it can be easily determined whether the tray supporting the substrate is aligned with the predetermined correct or precise position in the chamber. Further, by detecting the tilting or offsetting of the tray and then adjusting or replacing the tray, the process for the substrate can proceed more smoothly.

Furthermore, since predetermined reference values are referred to during an assembly of the substrate processing apparatus according to the present invention, the setting and assembly of the apparatus is enabled regardless of a tolerance in assembly and processing of the apparatus and a skill level of a worker. In addition, issues in the process, such as deformation and disassembly, which may occur due to a weight, a pressure, a temperature, and the like of the substrate processing apparatus, can be prevented in advance.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber providing a processing space for performing a process on a substrate on which a treatment liquid or an organic solvent is coated, using a fluid in a supercritical state;
a tray configured to allow the substrate to be seated thereon, the tray being configured to be loaded into an inside of the chamber and to be unloaded to an outside of the chamber, through an opening of the chamber; and
a detection sensor configured to detect a tilting or a horizontal offsetting of the tray.

2. The substrate processing apparatus of claim 1, wherein the detection sensor includes:
an emitter provided at any one of upper and lower portions of the chamber along a moving path of the tray and configured to emit light; and
a receiver provided at the other of the upper and lower portions of the chamber and configured to receive the light from the emitter, and
wherein the tray is formed with a through hole through which the light from the emitter passes.

3. The substrate processing apparatus of claim 2, wherein the through hole is configured in a form of an elongated hole extending along a moving direction of the tray.

4. The substrate processing apparatus of claim 2, wherein the tray includes the through holes formed at formed at a front end and a rear end of the tray along a moving direction of the tray, respectively.

5. The substrate processing apparatus of claim 2, wherein a shading rib is formed along an edge of the through hole on at least one of top and bottom surfaces of the tray in which the through hole is formed.

6. The substrate processing apparatus of claim 2, wherein the tilting or the horizontal offsetting of the tray is determined by detecting at least one of a reception of the light at the receiver, a reception duration of the light, and a reception sensitivity of the light.

7. A tray tilting detection method for a substrate processing apparatus, which includes a chamber providing a processing space for performing a process on a substrate, using a fluid in a supercritical state, and a tray configured to allow the substrate to be seated thereon, the tray being configured to be loaded into an inside of the chamber and to be unloaded to an outside of the chamber, through an opening of the chamber, the method comprising:
receiving, by a receiver, light which is emitted by an emitter and passes through a through hole of the tray, while the tray is moving; and
determining a tilting or a offsetting of the tray by detecting at least one of a reception of the light at the receiver, a reception duration of the light, and a reception sensitivity of the light.

8. The tray tilting detection method of claim 7, wherein the through hole includes:
a first hole formed at a front end of the tray; and
a second hole formed at a rear end of the tray, and
wherein when, upon movement of the tray, the reception durations measured at the first hole and the second hole are shorter than a pre-stored reference reception duration, it is determined that the tray is tilted about a first axis perpendicular to a direction of the movement of the tray.

9. The tray tilting detection method of claim 7, wherein the through hole includes:
a first hole formed at a front end of the tray; and
a second hole formed at a rear end of the tray, and
wherein when, upon movement of the tray, the reception sensitivities measured at the first hole and the second hole are smaller than a pre-stored reference reception sensitivity, it is determined that the tray is tilted about a second axis parallel to a direction of the movement of the tray.

10. The tray tilting detection method of claim 7, wherein the through hole includes:
a first hole formed at a front end of the tray; and
a second hole formed at a rear end of the tray, and
wherein when the light is not received by the receiver at both the first hole and the second hole, it is determined that the tray is offset by being moved horizontally along a first axis perpendicular to a direction of the movement of the tray.

11. The tray tilting detection method of claim 7, wherein the through hole includes:
a first hole formed at a front end of the tray; and
a second hole formed at a rear end of the tray, and
wherein, during movement of the tray, when no light is detected at any one of the first and second holes, or the reception sensitivity and the reception duration detected at any one of the first and second holes are less than a reference reception sensitivity and a reference reception duration, and when the reception sensitivity and the reception duration detected at the other of the first and second holes are similar to the reference reception sensitivity and the reference reception duration, it is determined that the tray is turned on a horizontal plane.
